(19) United States
(12) Patent Application Publication
(10) Pub. No.: US 2012/0120586 A1
(43) Pub. Date: May 17, 2012

(54) DEVICE, AND DEVICE MOUNTING APPARATUS

(75) Inventor: Keiji Katata, Saitama-ken (JP)

(73) Assignee: PIONEER CORPORATION, Kanagawa (JP)

(21) Appl. No.: 13/381,017

(22) PCT Filed: Jul. 6, 2009
(86) PCT No.: PCT/JP2009/062291

§ 371 Date: Dec. 27, 2011

(51) Int. Cl. H05K 7/00

(52) U.S. Cl. 361/679.32

(57) ABSTRACT

A device, and a device mounting apparatus providing ease of use similar to an optical disc, and a protection against erroneous ejection, while reducing cost, are provided. A memory device mounting apparatus, includes a memory device mounting unit in which a memory device can be mounted, the memory device including a nonvolatile semiconductor memory, a controller for controlling the writing and reading of data in and from the nonvolatile semiconductor memory, a host interface unit for the controller to communicate with a host computer, and a connection unit which is electrically connected to the controller. The device mounting apparatus includes a connection unit which is electrically connected to the connection unit of the memory device, an operation unit which receives an ejecting instruction of the memory device from a user, and an ejecting unit which includes an ejecting mechanism which ejects the memory device from the memory device mounting unit.

### TECHNICAL FIELD

The present invention relates to a technical field of a memory device comprising a nonvolatile semiconductor memory, a controller for controlling the reading and writing of data from and in the nonvolatile semiconductor memory, and a connecting unit electrically connected to the controller, and a mounting apparatus thereof. The present invention also relates to a technical field of a function device comprising a function circuit including a function other than a data memory and provided with a nonvolatile semiconductor memory, a controller for controlling the reading and writing of data from and in the function circuit, and a connecting unit electrically connected to the controller, and amounting apparatus thereof.

### BACKGROUND ART

In a conventional optical disc drive (hereinafter, referred to as “ODD”), when a user start to use an optical disc (for example, CD, DVD, BD, etc.), he opens a tray of ODD, sets an optical disc therein, and closes the tray, or inserts an optical disc into a slot of ODD. Based thereon, when the ODD detects the insertion of the optical disc, the ODD supplies a signal to a host computer (hereinafter, referred to as “host”) which is connected to the ODD, and the host starts to read data recorded in the optical disc through the ODD.

On the other hand, when a user ends the use of an optical disc, he pushes an ejecting button of an ODD. Based thereon, when the ODD detects the pushing of the ejecting button, the ODD transmits an ejecting request (information indicative of an ejecting request (an extraction request)) to a host, the host terminates the operation of the ODD, and transmits an ejecting command to the ODD. When the ODD receives the ejecting command, the ODD terminates the operation of an optical disc, and ejects the optical disc. Here, in the case where the host cannot terminate the operation of the ODD, the host displays, on a display, information indicating that the host cannot correspond to an ejecting request transmitted from the ODD, and the host does not transmit an ejecting command to the ODD. Further, in the case where the ODD cannot terminate the operation of the optical disc, the ODD is arranged to terminate, as an error, an ejecting command transmitted from the host, and is arranged not to eject the optical disc.

Thus, in an ODD, irrespective of a sort of software in a host, a user can insert and eject an optical disc intuitively by the same method (with ease of use), and can carry the optical disc. At the same time, when an optical disc is ejected, data in the optical disc, and software in a host which accesses the optical disc, are protected.

Further, in recent years, a memory device of removable card type, in which semiconductor memories with some standards such as PCMCIA, Flash card, Compact Flash card, SD card, or Memory Stick are used, becomes popular. When a memory device of card type is used, it is mounted in a mounting unit of a host. When the use of the memory device is terminated, it is ejected from the mounting unit of the host.

In a memory device body of card type or a mounting unit thereof, however, there is not an eject button mentioned above for a user to instruct an ejection of a memory device, resulting in a user being able to eject a memory device from a mounting unit before a host terminates an operation of the memory device. For example, if a user ejects a memory device from a mounting unit while an application (software) is still executed, there is a possibility that an application crashes, data to be written in a memory device is destroyed, or a writing operation is forced to terminate before its completion. Therefore, in such a memory device of card type, a protection against an erroneous ejection is not enough.

A removable function device of the same card type, in which a function circuit with a radio communication function or the like is installed, becomes popular. When such a function device of card type is used, it is mounted in a mounting unit of a host. When the use of the memory device is terminated, it is ejected from the mounting unit of the host.

Similarly with a memory device of card type mentioned above, however, there is not an eject button mentioned above for a user to instruct an ejection of a function device in a function device body of card type or a mounting unit thereof, resulting in a user being able to eject a function device from a mounting unit before a host terminates an operation of the function device. For example, if a user ejects a function device from a mounting unit while an application (software) is still executed, there is a possibility that an application crashes, control data of device driver software for handling a function device is destroyed, or it is not erased from a memory of a host and its operation terminates. In the case where control data of device driver software for handling a function device is destroyed, and it is not erased from a memory of a host, and is maintained, even if the function device is mounted in a host again, the function device is not recognized by the host, resulting in an application being not able to be used appropriately. Therefore, in such a function device of card type, a protection against an erroneous ejection is not enough. An operation of ejection varies with an application software, and therefore, it is difficult to understand an operation of ejection, as compared with an ODD.

On the other hand, in Patent Document No. 1, a technology of a detachable hard disc drive (hereinafter, referred to as “HDD”) of small type is disclosed. In this technology, based on a pushing operation of an ejection operational member by a user, an HDD or an HD cartridge can be removed from a portable computer, and further, a data destruction or the like can be prevented even if an ejection operational member is pushed during a data access to an HD. In a technology disclosed in Patent Document No. 1, however, a special mechanism is necessary to detachably contain an HDD in a portable computer, and further, a special interface is necessary to electrically connect an HDD to a portable computer, and therefore, there is a problem in that an interface of general purpose (for example, a USB interface) cannot be used.

### PRIOR ART DOCUMENT

### Patent Document

Patent Document No. 1: Japanese Patent Laid-open No. 8-212016

### SUMMARY OF THE INVENTION

### Problems to be Solved by the Invention

In recent years, an SSD (Solid State Drive) is known as a memory device comprising a nonvolatile semiconductor memory, a controller for controlling the reading and writing of data from and in the nonvolatile semiconductor memory, and an interface of general purpose for communicating with a host.

Since this SSD is generally thought to be substituted for an HDD, it is arranged to be screw-clamped to a mounting unit of a host, for example, and an arrangement in which a SSD is substituted for an optical disc and is used is expected. That is, this is an arrangement in which a user can easily insert and eject an SSD similarly with an optical disc, and carry it.

While an interface of general purpose can be used in the present SSD, however, the present SSD is not enough in light of the ease of use similar with an optical disc, and in light of the above-mentioned protection against an erroneous ejection (a guarantee in a data access). In addition thereto, since a controller is contained in the present SSD, the present SSD is more expensive than an optical disc, and therefore, an unnecessary cost needs to be restricted as much as possible in order to realize an arrangement in which an SSD is substituted for a conventional optical disc and is used.

Therefore, it is an object of the present invention to solve the above problems, and to provide a device, and a device mounting apparatus capable of realizing the ease of use similar with an optical disc, and a protection against an erroneous ejection, while restricting a cost as much as possible.

### Means for Solving the Problems

In order to solve the above problems, the invention according to a first embodiment relates to a device mounting apparatus, comprising a device mounting unit in which a device can be mounted,

the device including a nonvolatile semiconductor memory, a controller for controlling the writing and reading of data in and from the nonvolatile semiconductor memory, a host interface unit for the controller to communicate with a host computer, and a connection unit which is electrically connected to the controller,

wherein the device mounting unit comprises a connection unit which is electrically connected to the connection unit of the device, an operation unit which receives an ejecting instruction of the device from a user, and an ejecting unit which includes an ejecting mechanism which ejects the device from the device mounting unit, and

wherein when the connection unit of the device mounting apparatus receives an ejecting instruction signal indicative of the ejecting instruction which is outputted from the operation unit, the connection unit of the device mounting apparatus outputs the ejecting instruction signal to the controller of the device through the connection unit of the device, and then, when the connection unit of the device mounting apparatus receives a driving signal for driving the ejecting mechanism which is outputted from the controller of the device through the connection unit of the device, the connection unit of the device mounting apparatus outputs the driving signal to the ejecting unit.

The invention according to another embodiment relates to a device, comprising a nonvolatile semiconductor memory, a controller for controlling the writing and reading of data in and from the nonvolatile semiconductor memory, a host interface unit for the controller to communicate with a host computer, and a connection unit which is electrically connected to the controller,

wherein the device can be mounted in a device mounting unit of a device mounting apparatus which includes a connection unit which is electrically connected to the connection unit of the device, an operation unit which receives an ejecting instruction of the device from a user, and an ejecting unit which includes an ejecting mechanism which ejects the device from the device mounting unit, and

wherein when the controller receives an ejecting instruction signal indicative of the ejecting instruction through the connection unit, the controller transmits information indicative of an ejecting request to the host computer through the host interface unit, and then, when the controller receives information indicative of an ejecting command from the host computer through the host interface unit, the controller outputs s driving signal for driving the ejecting mechanism to the ejecting unit through ejecting unit through the connection unit.

### BRIEF DESCRIPTION OF DRAWINGS

FIG. 1 is a view showing an example of an internal arrangement of a memory device 1 and a memory device mounting apparatus 2, and a mode of connection between a memory device 1, a memory device mounting apparatus 2, and a host 4.

FIG. 2A is a flowchart showing a process of a controller 12 in a memory device 1, and FIG. 2B is a flowchart showing a process of a host 4 (CPU).

FIG. 3 is a view showing an example of an internal arrangement of a SSD card 1 and an SSD card mounting apparatus 2, and a mode of connection between an SSD card, an SSD card mounting apparatus 2, and a host 4.

FIG. 4 is a view showing an example of a more detailed arrangement of the inside of an SSD card 1.

FIG. 5 is a view showing an example of a more detailed arrangement of the inside of an SSD card mounting apparatus 2.

### MODE FOR CARRYING OUT THE INVENTION

Hereinafter, an embodiment of the present invention will be described with reference to the accompanying drawings. An embodiment described below is one in which the present invention is applied to a memory device mainly used as a data storing function, and a memory device mounting apparatus.

### 1. An Arrangement of a Memory Device, and a Memory Device Mounting Apparatus

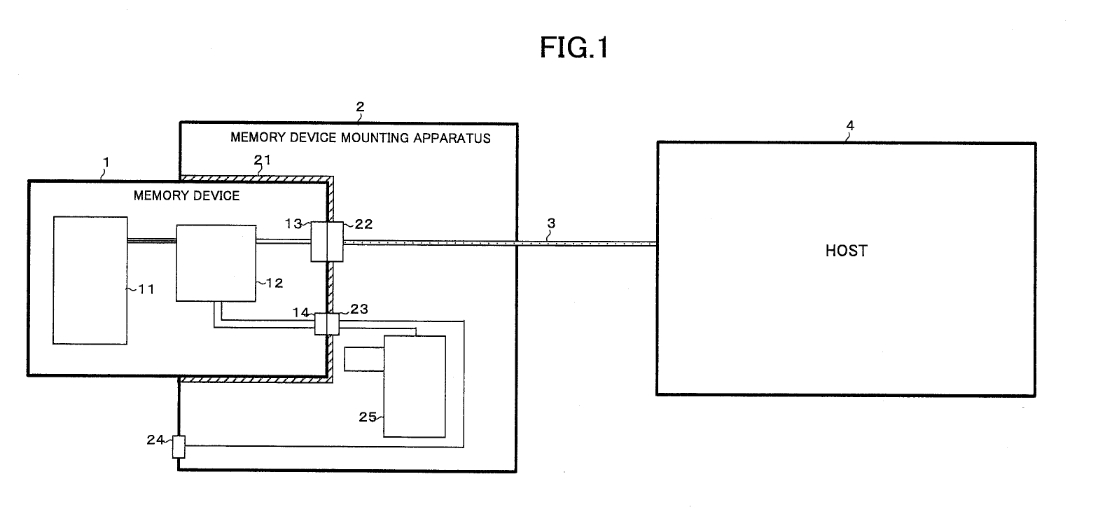

Referring first to FIG. 1, an arrangement of a memory device (an example of a device in the present invention) and a memory device mounting apparatus (an example of a device mounting apparatus in the present invention) according to an embodiment of the present invention will be described.

FIG. 1 is a view showing an example of an internal arrangement of a memory device 1 and a memory device mounting apparatus 2, and a mode of connection between a memory device 1, a memory device mounting apparatus 2, and a host 4. Herein, although the memory device 1 is detachable from the memory device mounting apparatus 2 (a memory device mounting unit 21), an example in FIG. 1 shows a condition in which the memory device 1 is mounted in the memory device mounting apparatus 2.

As shown in FIG. 1, the memory device 1 is arranged to comprise a nonvolatile semiconductor memory 11, a controller 12, a host interface unit 13, and a connection unit 14. On the other hand, the memory device mounting apparatus 2 is arranged to comprises the memory device mounting unit 21, a host interface unit 22, a connection unit 23, a operation unit 24, and an ejecting unit 25.

The nonvolatile semiconductor memory 11 is, for example, an EEPROM (Electrically Erasable Programmable Read Only Memory), and stores a variety of data.

The controller 12 is arranged to comprise, for example, a CPU (Central Processing Unit), a RAM (Random Access Memory), a ROM, and the like, and controls the reading and writing of data from and in the nonvolatile semiconductor memory 11, and communicates with the host 4 through the host interface units 13, and 22, and an interface cable 3. For example, a personal computer can be used as the host 4.

The host interface units 13, and 22 are contact points of a general-purpose interface for the controller 12 to communicate with the host 4 (for example, a USB (Universal Serial Bus) interface, or a serial ATA interface). In a condition where the memory device 1 is mounted in the memory device mounting unit 21, the host interface unit 13 and the host interface unit 22 are arranged to be electrically connected to each other. A contact point of general-purpose interface to be connected to the interface cable 3 is also provided at a side of the host 4.

The connection unit 14 is, for example, a contact point which is electrically connected to the controller 12 through a wiring pattern. On the other hand, the connecting unit 23 is, for example, a contact point which is electrically connected to the operation unit 24, and the ejecting unit 25 through a wiring pattern. In a condition where the memory device 1 is mounted in the memory device mounting unit 21, the connection unit 14 is arranged to be electrically connected to the connecting unit 23.

The operation unit 24 is, for example, an ejecting button of electric type which receives an instruction of ejecting the memory device 1 from a user.

The ejecting unit 25 is one of electric type which includes an ejecting mechanism which ejects the memory device 1 from the memory device mounting unit 21.

Here, the term “eject” means that an electrical connection between the memory device 1 and the memory device mounting apparatus 2, and a electrical connection between the memory device 1 and the host 4 are released, and the memory device 1 moves (for example, slides for about 5 mm) from a position where the memory device 1 is mounted in the memory device mounting unit 21 (a position shown in FIG. 1) to a position where a user is easy to take out. A variety of known technology can be used as a mechanical structure of the ejecting unit 25, so a detailed explanation thereof will be omitted.

By the way, while the memory device mounting apparatus 2 is arranged to comprise the operation unit 24, and the ejecting unit 25 in an example of FIG. 1, the operation unit 24, and the ejecting unit 25 may be arranged to be provided outside the memory device mounting apparatus 2. Further, the memory device mounting apparatus 2 may be arranged to be contained in a box of the host 4, or may be arranged to be provided outside a box of the host 4.

### 2. An Operation of a Memory Device 1 and a Host 4

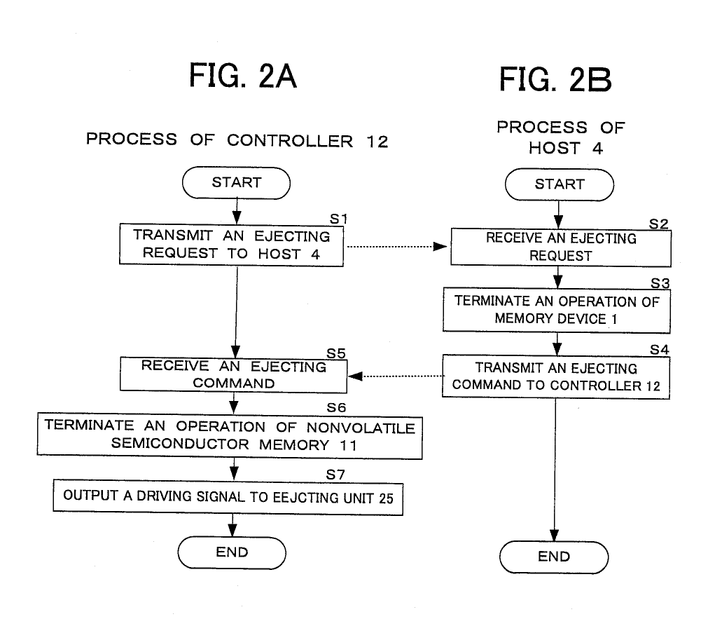

Referring now to FIG. 2, an operation of the memory device 1 and the host 4 will be described.

FIG. 2A is a flowchart showing a process of a controller 12 in a memory device 1, and FIG. 2B is a flowchart showing a process of a host 4 (CPU).

A process in FIG. 2 is started, when the controller 12 of the memory device 1 detects an instruction of ejecting the memory device 1 on the basis of an operation of the operation unit 24 by a user (for example, the pushing of an ejecting button of electric type) in a condition where the memory device 1 is mounted in the memory device mounting unit 21.

That is, when a user operates the operation unit 24, an ejecting instruction signal (for example, an ON signal) indicative of an instruction of ejecting the memory device 1 is outputted from the operating unit 24 to the connection unit 23. When the connection unit 23 receives the ejecting instruction signal outputted from the operating unit 24, the connection unit 23 outputs the ejecting instruction signal to the connection unit 14. When the connection unit 14 receives the ejecting instruction signal outputted from the connection unit 23, the connection unit 14 outputs the ejecting instruction signal to the controller 12. When the controller 12 receives the ejecting instruction signal outputted from the connection unit 14, the controller 12 detects an ejecting instruction of the memory device 1.

Thus, when the controller 12 detects the ejecting instruction of the memory device 1 (i.e., receives the ejecting instruction signal), the controller 12 transmits an ejecting request (information indicative of an ejecting request) to the host 4 through the host interface units 13, 22, and the interface cable 3 (step S1).

Then, when the host 4 receives an ejecting request (step S2), for example, in order for a write data in Write Back Cache to be written in the nonvolatile semiconductor memory 11 of the memory device 1, the host 4 transmits (writes) the write data to the controller 12 through the host interface units 13, 22, and the interface cable 3, and terminates an operation of the memory device 1 (for example, terminates an application of play-back of video, and so on) (step S3).

Then, the host 4 transmits an ejecting command (information indicative of an ejecting command) to the controller 12 through the host interface units 13, 22, and the interface cable 3 (step S4).

Then, when the controller 12 receives an ejecting command from the host 4 through the host interface unit 13 and so on (step S5), the controller 12 terminates an operation of the nonvolatile semiconductor memory 11, for example, an operation of writing data (step S6).

Then, the controller 12 outputs a driving signal (for example, an ON signal) for driving an ejecting mechanism of the ejecting unit 25 to the ejecting unit 25 through the connection units 14, 23 (step S7). That is, when the connection unit 23 of the memory device mounting apparatus 2 receives a drive signal outputted from the connecting unit 14 of the memory device 1, the connection unit 23 outputs the drive signal to the ejecting unit 25. Thus, an ejecting mechanism is driven, and the memory device 1 is ejected from the memory device mounting unit 21.

As mentioned above, in accordance with the above embodiment, an arrangement is follows: the connection unit 14 provided to the memory device 1 and the connection unit 23 provided to the memory device mounting unit 2 are connected to each other, and in the case where a user operates the operation unit 24 to give instructions to eject the memory device 1, the information is transmitted to the host 4 through the connection unit 14, the connection unit 23, the controller 12, and a general-purpose interface. When the controller 12 receives an ejecting command from the host 4 through a general-purpose interface, the controller 12 drives the ejecting unit 25 through the connecting unit 14 and the connecting unit 23 to eject the memory device 1. Therefore, an process of ejecting the memory device 1 is not based on a software in the host 4, a protection against an erroneous ejecting of the memory device 1 (assurance in data-access) can be realized with the same ease of use as an optical disc. Further, since the controller 12 and a general-purpose interface can be used in a process of ejecting the memory device 1, it is not necessary to newly provide the memory device mounting apparatus 2 with a controller for controlling the ejection, or provide a specific interface. Therefore, it is possible to keep down a cost to the utmost.

### 3. Embodiment

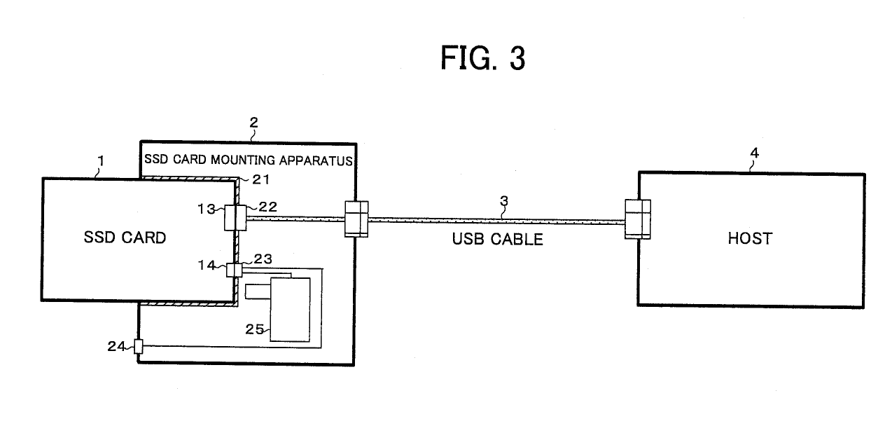

Referring now to FIGS. 3 to 5, a more detailed embodiment of a memory device 1, and a memory device mounting apparatus 2 will be described. The embodiment is one where a memory device 1 is an SSD (Solid State Drive) card 1 having a USB interface, and a memory device mounting apparatus 2 is an SSD card mounting apparatus.

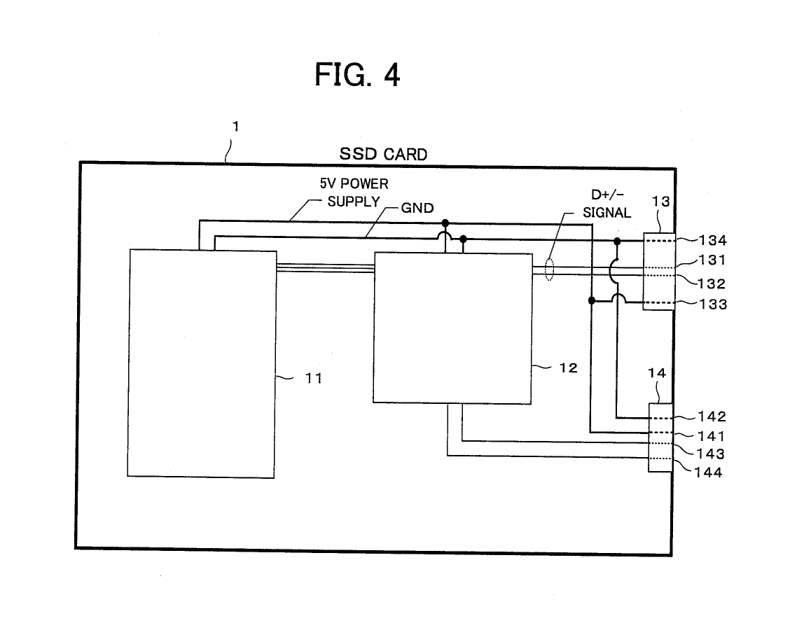

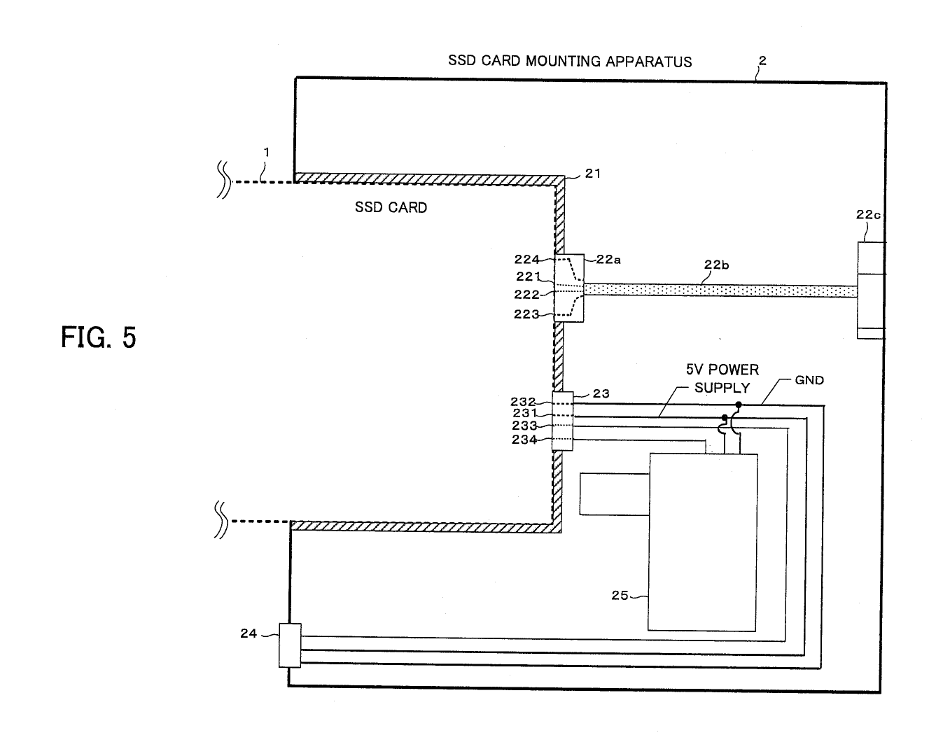

FIG. 3 is a view showing an example of an internal arrangement of a SSD card 1 and an SSD card mounting apparatus 2, and a mode of connection between an SSD card, an SSD card mounting apparatus 2, and a host 4. FIG. 4 is a view showing an example of a more detailed arrangement of the inside of an SSD card 1. FIG. 5 is a view showing an example of a more detailed arrangement of the inside of an SSD card mounting apparatus 2.

In the embodiment, an SSD card mounting apparatus 2 and a host 4 are connected to each other through a USB cable 3, as shown in FIG. 3.

As shown in FIG. 4, an SSD card 1 comprises a nonvolatile semiconductor memory 11, a controller 12, a USB interface contact 13 as a host interface unit, and a connection unit 14. The SSD card 1 in the embodiment is different from a known SSD card in that the connection unit 14 is provided in the SSD card 1 in the embodiment.

Here, contacts (pins) 131, 132 for a signal (balanced transmission), a contact 133 for a 5V power supply, and a contact 134 for GND are provided in the USB interface contact 13. The contacts 131, 132 for a signal are electrically connected to the controller 12, for example, through a wiring pattern. The contact 133 for a 5V power supply, and the contact 134 for GND are electrically connected to the nonvolatile semiconductor memory 11, the controller 12, and the connection unit 14, for example, a power supply wiring. Thus, power is supplied from the host 4 to the nonvolatile semiconductor memory 11, the controller 12, and the connection unit 14.

Further, a contact 141 for a 5V power supply which is connected to the contact 133 for a 5V power supply, a contact 142 for GND which is connected to the contact 134 for GND, a contact 143 for an ejecting instruction signal from an operation unit 24, and a contact 144 for a driving signal to an ejecting unit 25 are provided in the connection unit 14. The contact 143 for an ejecting instruction signal, and the contact 144 for a driving signal are electrically connected to the controller 12, for example, through a wiring pattern.

On the other hand, as shown in FIG. 5, the SSD card mounting apparatus 2 is arranged to comprise an SSD card mounting unit 21, a connection unit 23, an operation unit 24, and an ejecting unit 25, and further comprise a USB interface contact 22a, a USB cable 22b, and a USB connector 22c as a host interface unit. The USB interface contact 22a is connected to a USB cable 3 through the USB cable 22b, and the USB connector 22c.

Here, contacts 221, 222 for a signal which are connected to the contacts 131, 132 for a signal, a contact 223 for a 5V power supply which is connected to the contact 133 for a 5V power supply, and a contact 224 for GND which is connected to the contact 134 for GND, are provided in the USB interface contact 22a.

Further, a contact 231 for a 5V power supply which is connected to the contact 141 for a 5V power supply, a contact 232 for GND which is connected to the contact 142 for GND, a contact 233 for an ejecting instruction signal which is connected to the contact 143 for an ejecting instruction signal, and a contact 234 for a driving signal which is connected to the contact 144 for a driving signal, are provided in the connection unit 23. The contact 231 for a 5V power supply, and the contact 232 for GND are electrically connected to the operation unit 24, and the ejecting unit 25, for example, through a wiring for a power supply. Thus, in a condition where the SSD card 1 is mounted in the SSD card mounting unit 21, power is supplied from the host 4 to the operation unit 24, and the ejecting unit 25.

Further, the contact 233 for an ejecting instruction signal is electrically connected to the operation unit 24, for example, through a wiring pattern, and the contact 234 for a driving signal is electrically connected to the ejecting unit 25, for example, through a wiring pattern.

An operation of the SSD card 1, and the host 4 is the same as a process explained with respect to FIG. 2, so an overlapped explanation will be omitted.

As mentioned above, in accordance with the above embodiment, only by additionally providing the connection unit 14 to an existing SSD card, and by additionally providing the connection unit 23, the operation unit 24, and the ejecting unit 25 to an existing SSD card mounting apparatus, in a process of ejecting the SSD card 1, a protection against an erroneous ejecting of the SSD card 1 (assurance in data-access) can be realized with the same ease of use as an optical disc irrespective of a software in the host 4, while restricting a cost as much as possible.

Further, in the case of an existing inexpensive SSD card, there is a problem in that a multi level chip whose writing speed is low (a chip in which 3 to 4 bits are stored for one memory element) with respect to a memory size of a write back cache in the host 4 is used, and a user erroneously ejects an SSD card before a writing data in a write back cache is written in the SSD card. In accordance with the embodiment, however, it is possible to overcome the problem.

In the above embodiment, a contact for a 5V power supply, and a contact for GND are provided in the connection unit 14, and the connection unit 23, and a wire for a power supply passes through the SSD card 1. Therefore, when the SSD card 1 is ejected from the SSD card mounting apparatus 21, a power is turned off, and it is possible that a leak current becomes null. As an alternative example, without providing the connection unit 14, and the connection unit 23 with a contact for a 5V power supply, and a contact for GND, an arrangement in which a wire for a power supply is connected from the USC interface contact 22a to the operation unit 24 and the ejecting unit 25 may be possible. In accordance with this arrangement, although it is not possible that a leak current to the operation unit 24, and the ejecting unit 25 becomes null, it is possible to reduce the number of contacts (pins) in the connection unit 14, and the connection unit 23.

Further, in the above embodiment, an arrangement is as follows: a contact for an ejecting instruction signal, and a contact for a driving signal are separately provided in each of the connection unit 14, and the connection unit 23, and further, two wiring patterns for an ejecting instruction signal, and a driving signal are provided in each of them. As an alternative example, the following arrangement may be possible: a contact for an ejecting instruction signal, and a contact for a driving signal become to one (i.e., shared), and one wiring pattern for an ejecting instruction signal, and a driving signal is provided. In this case, for example, assuming that 2.5V is a boundary, a distinction is made as follows: in the case where an ON signal has a voltage level higher than 2.5V, it is recognized an ejecting instruction signal, and in the case where the ON signal has a voltage level lower than 2.5V, it is recognized as a driving signal. In accordance with this arrangement, it is possible to reduce the number of contacts, and the number of wiring patterns in the connection unit 14, and the connection unit 23.

Further, in the above embodiment, a case in which a memory device according to the present invention is applied to an SSD card has been explained. However, it may be possible to apply the present invention to another memory device which has the same arrangement as an SSD card.

Further, in the above embodiment, a case, in which a device according to the present invention has been applied to an SSD card in which a data storage function of a nonvolatile semiconductor memory 11 is mainly used, has been explained. However, it may be possible that the present invention is applied to a function device which includes a few nonvolatile semiconductor memory 11, and a function circuit which has a function of another purpose (for example, a radio communication function). As an example of this function device, a wireless LAN card, a video accelerator card, a terrestrial digital tuner card, and the like are listed.

### DESCRIPTION OF REFERENCE NUMERALS

1: memory device
2: memory device mounting apparatus
3: interface cable
4: host
11: nonvolatile semiconductor memory
12: controller
13: host interface unit
14: connection unit
21: memory device mounting unit
22: host interface unit
23: connection unit
24: operation unit
25: ejecting unit

1-7. (canceled)

8. A device mounting apparatus, comprising a device mounting unit in which a device can be mounted,
the device including a nonvolatile semiconductor memory, a controller for controlling the writing and reading of data in and from the nonvolatile semiconductor memory, a host interface unit for the controller to communicate with a host computer, and a connection unit which is electrically connected to the controller,
wherein the device mounting unit comprises a connection unit which is electrically connected to the connection unit of the device, an operation unit which receives an ejecting instruction of the device from a user, and an ejecting unit which includes an ejecting mechanism which ejects the device from the device mounting unit, and
wherein when the connection unit of the device mounting apparatus receives an ejecting instruction signal indicative of the ejecting instruction which is outputted from the operation unit, the connection unit of the device mounting apparatus outputs the ejecting instruction signal to the controller of the device through the connection unit of the device, and then, when the connection unit of the device mounting apparatus receives a driving signal for driving the ejecting mechanism which is outputted from the controller of the device through the connection unit of the device, the connection unit of the device mounting apparatus outputs the driving signal to the ejecting unit.

9. A device mounting apparatus according to claim 8,
further comprising the operation unit, and the ejecting unit.

10. A device mounting apparatus according to claim 8,
wherein the host interface unit is an interface contact of USB (Universal Serial Bus).

11. The device which can be mounted in a device mounting apparatus according to claim 8, comprising:
the nonvolatile semiconductor memory, the controller for controlling the writing and reading of data in and from the nonvolatile semiconductor memory, the connection unit which is electrically connected to the controller, and the host interface unit for communicating with a host computer,
wherein the connection unit of the device is electrically connected to the connection unit of the device mounting apparatus.

12. A device, comprising a nonvolatile semiconductor memory, a controller for controlling the writing and reading of data in and from the nonvolatile semiconductor memory, a host interface unit for the controller to communicate with a host computer, and a connection unit which is electrically connected to the controller,
wherein the device can be mounted in a device mounting unit of a device mounting apparatus which includes a connection unit which is electrically connected to the connection unit of the device, an operation unit which receives an ejecting instruction of the device from a user, and an ejecting unit which includes an ejecting mechanism which ejects the device from the device mounting unit, and
wherein when the controller receives an ejecting instruction signal indicative of the ejecting instruction through the connection unit, the controller transmits information indicative of an ejecting request to the host computer through the host interface unit, and then, when the controller receives information indicative of an ejecting command from the host computer through the host interface unit, the controller outputs a driving signal for driving the ejecting mechanism to the ejecting unit through ejecting unit through the connection unit.

13. A device according to claim 11,
wherein the device is a memory device in which a data storing function is mainly used, or a function device which includes a function circuit which has a function of another purpose.
